(19) United States
(12) Patent Application Publication
(10) Pub. No.: US 2020/0221611 A1
(43) Pub. Date: Jul. 9, 2020

(54) POWER CONVERSION DEVICE AND AIR-CONDITIONING APPARATUS

(71) Applicant: Mitsubishi Electric Corporation, Tokyo (JP)

(72) Inventors: Takahiko KOBAYASHI, Tokyo (JP); Shinsaku KUSUBE, Tokyo (JP); Keiji HARADA, Tokyo (JP); Masaki MURAMATSU, Tokyo (JP)

(21) Appl. No.: 16/647,088

(22) PCT Filed: Nov. 30, 2017
(86) PCT No.: PCT/JP2017/043107

§ 371 Date: Mar. 13, 2020

(51) Int. Cl. H05K 7/20; H02M 7/00; F24F 11/88; F24F 11/70; H02P 29/60

(52) U.S. Cl. CPC H05K 7/20945; H02M 7/003; H02P 29/60; F24F 11/70; F24F 11/88

(57) ABSTRACT

A power conversion device includes a rectifier module configured to rectify an alternating current supplied from an alternating-current power supply; an inverter unit configured to convert a direct current rectified by the rectifier module into an alternating current, output the alternating current to an electric motor, and drive the electric motor; and a cooling mechanism. The inverter unit has a plurality of inverter modules. The cooling mechanism is configured to cool the rectifier module and the plurality of inverter modules. Thermal resistance between the rectifier module and the cooling mechanism and thermal resistance between the plurality of inverter modules and the cooling mechanism are different from each other.

### TECHNICAL FIELD

The present disclosure relates to power conversion devices provided with inverter modules, and to air-conditioning apparatuses provided with power conversion devices.

### BACKGROUND ART

In the related art, switching elements of inverter modules are manufactured by mounting square chips cut out from circular wafers onto, for example, metallic plates. Wafers have crystal defects, and chips with crystal defects cannot be used for switching elements. When the chip area is large, the probability that the chips may contain crystal defects in the chips increases, and the yield rate of inverter modules thus decreases. In contrast, when the chip area is small, the probability that the chips may contain crystal defects in the chips can be decreased, and the yield rate of inverter modules can be improved. Accordingly, the yield rate is improved by reducing the chip area, and cost reduction of inverter modules can be thus achieved.

As compared with an inverter module having a switching element with a large chip area mounted on the inverter module, an inverter module having a switching element with a small chip area mounted on the inverter module has a lower current carrying capacity. However, a high current configuration can be achieved by connecting, in parallel, inverter modules each having a switching element with a small chip area. Thus, with reference to a comparison based on the same current carrying capacity, cost reduction may be achievable by connecting, in parallel, the inverter modules each having a switching element with a small chip area rather than using a single inverter module having a switching element with a large chip area.

In an electric-motor driving device, there is a single three-phase inverter constituted by using a plurality of inverter modules connected in parallel. In the case of this configuration, the plurality of inverter modules are disposed in a distributed manner. When the inverter modules are to be used, it is necessary to prevent a thermal failure of the inverter modules by appropriately cooling the heat generated from the inverter modules to maintain the temperature lower than or equal to a predetermined temperature at which a thermal failure does not occur. However, when the plurality of inverter modules are cooled using a natural-draft-based air-cooling method, uneven cooling occurs because of the relative position between a heat sink in contact with each inverter module and the inverter module, and it is thus difficult to cool all of the inverter modules evenly. In particular, in a high current configuration, the cooling performance is not high in this air-cooling method, and an inverter module that does not appropriately receive the air may be cooled insufficiently.

Furthermore, in a case where a rectifier module provided in addition to the inverter modules is to convert an alternating current supplied from a three-phase alternating-current power supply into a direct current and to supply the direct current to the inverter modules, the rectifier module also has to be cooled to prevent a thermal failure.

A rectifier module and an inverter module have significantly different heat values as the rectifier module and the inverter module have different heat generating properties. The heat value of a rectifier module increases substantially proportional to the magnitude of input alternating-current power. In other words, the heat value of a rectifier module increases substantially proportional to the magnitude of direct-current power output after the direct-current power is converted from input alternating-current power. In contrast, an inverter module has a correlative relationship between the magnitude of an electric current output from the inverter module and the heat value of the inverter module. Therefore, even in an input power condition in which the heat value of the rectifier module is small, when the electric current to be output from the inverter module is high, the heat value of the inverter module is larger than the heat value of the rectifier module. As a result, a large difference lies between the heat value of the inverter module and the heat value of the rectifier module.

Patent Literature 1 discloses a technology for cooling the heat from an element of a power module, that is, an inverter module, by transferring the heat to refrigerant flowing through a pipe in a refrigeration cycle of an air-conditioning apparatus. Specifically, the heat is transferred to the refrigerant by disposing the inverter module in contact with an electric-heat-plate cooling plate provided with a pipe through which the refrigerant flows, and the heat is thus cooled.

### CITATION LIST

### Patent Literature

Patent Literature 1: Japanese Patent No. 4488093

### SUMMARY OF INVENTION

### Technical Problem

The cooling method discussed in Patent Literature 1 has higher cooling performance than the natural-draft-based air-cooling method and is suitable as a cooling method for a high current configuration. However, when the inverter module and the rectifier module are to be cooled by using this method, as described above, the heat value of the inverter module becomes larger than the heat value of the rectifier module, and a large difference is thus caused between the two heat values. This large difference leads to the following problem. When cooling is performed to correspond to the heat value of the inverter module, the inverter module can be appropriately cooled, whereas the rectifier module is subcooled. This subcooled rectifier module causes the air surrounding the rectifier module to be cooled, and thus condensed into dew. When condensation occurs, the insulation properties of the rectifier module may deteriorate because of the condensation, and a failure may be thus caused. On the other hand, when the cooling performance is lowered to correspond to the heat value of the rectifier module, the rectifier module can be appropriately cooled, whereas the cooling performance is insufficient for the inverter module, and a thermal failure may thus occur in the inverter module.

Furthermore, when a wide-bandgap semiconductor is used for a switching element of the inverter module, the heat value per unit area is reduced, as compared with Si, that is, silicon. Therefore, the magnitude relationship between the heat value of the inverter module and the heat value of the rectifier module is inverted, and the inverter module may be thus subcooled.

As described above, there is a problem in that it is difficult to cool these modules, including the rectifier module, to a desired temperature range, that is, a temperature range in which a thermal failure of the modules does not occur and in which condensation does not occur around the modules. In particular, this problem is obvious in the case of the cooling method discussed in Patent Literature 1 that involves transferring the heat generated from the modules to the refrigerant flowing through the pipe in the refrigeration cycle of the air-conditioning apparatus.

The present disclosure has been made to solve the aforementioned problem. An object of the present disclosure is to provide a power conversion device that can cool a rectifier module and an inverter module to a temperature range in which a thermal failure does not occur and in which condensation does not occur around the modules, and to provide an air-conditioning apparatus provided with this power conversion device.

### Solution to Problem

A power conversion device according to an embodiment of the present disclosure includes a rectifier module configured to rectify an alternating current supplied from an alternating-current power supply; an inverter unit configured to convert a direct current rectified by the rectifier module into an alternating current, output the alternating current to an electric motor, and drive the electric motor, the inverter unit having a plurality of inverter modules; and a cooling mechanism configured to cool the rectifier module and the plurality of inverter modules. The cooling mechanism is configured in such a manner that thermal resistance between the rectifier module and the cooling mechanism is different from thermal resistance between the plurality of inverter modules and the cooling mechanism.

An air-conditioning apparatus according to an embodiment of the present disclosure includes the aforementioned power conversion device, a compressor configured to use the electric motor as a driving source, a heat-source-side heat exchanger, a load-side heat exchanger, a heat-source-side expansion valve, a load-side expansion valve, and a controller. A refrigerant circuit includes the compressor, the heat-source-side heat exchanger, the heat-source-side expansion valve, the load-side expansion valve, and the load-side heat exchanger that are sequentially connected by the pipe. The controller is configured to control a flow rate of the refrigerant flowing through the pipe on the basis of a heat value of at least one of the rectifier module and the plurality of inverter modules.

### Advantageous Effects of Invention

The power conversion device and the air-conditioning apparatus according to embodiments of the present disclosure can achieve an advantage of preventing or reducing condensation caused by subcooling of the plurality of inverter modules of the inverter unit and the rectifier module, and can also achieve an advantage of cooling the plurality of inverter modules and the rectifier module to a desired temperature range in which a thermal failure does not occur.

### BRIEF DESCRIPTION OF DRAWINGS

FIG. 1 is a diagram illustrating the overall configuration of a power conversion device according to Embodiment 1 of the present disclosure.

FIG. 2 is a diagram schematically illustrating a module cooling mechanism according to Embodiment 1 of the present disclosure.

FIG. 3 is a diagram schematically illustrating the module cooling mechanism according to Embodiment 1 of the present disclosure.

FIG. 4 is a diagram illustrating the positional relationships among modules on a cooling plate according to Embodiment 1 of the present disclosure.

FIG. 5 is a diagram illustrating the positional relationships among the modules on the cooling plate according to Embodiment 1 of the present disclosure.

FIG. 6 is a diagram illustrating a cooling structure for modules and capacitors in the power conversion device according to Embodiment 1 of the present disclosure.

FIG. 7 is a diagram schematically illustrating a module cooling mechanism according to Embodiment 2 of the present disclosure.

FIG. 8 is a diagram schematically illustrating the module cooling mechanism according to Embodiment 2 of the present disclosure.

FIG. 9 is a diagram illustrating the configuration of a refrigerant circuit according to Embodiment 3 of the present disclosure.

FIG. 10 is a diagram schematically illustrating a module cooling mechanism according to Embodiment 3 of the present disclosure.

FIG. 11 is a diagram illustrating the configuration of an air-conditioning apparatus according to Embodiment 4 of the present disclosure.

### DESCRIPTION OF EMBODIMENTS

A power conversion device and an air-conditioning apparatus according to Embodiment 1 to Embodiment 4 of the present disclosure will be described in detail below with reference to the drawings. The present disclosure is not to be limited to Embodiment 1 to Embodiment 4 to be described below. Furthermore, the sizes and shapes of components in the drawings may differ from the sizes and shapes of components in the actual device or apparatus.

### Embodiment 1

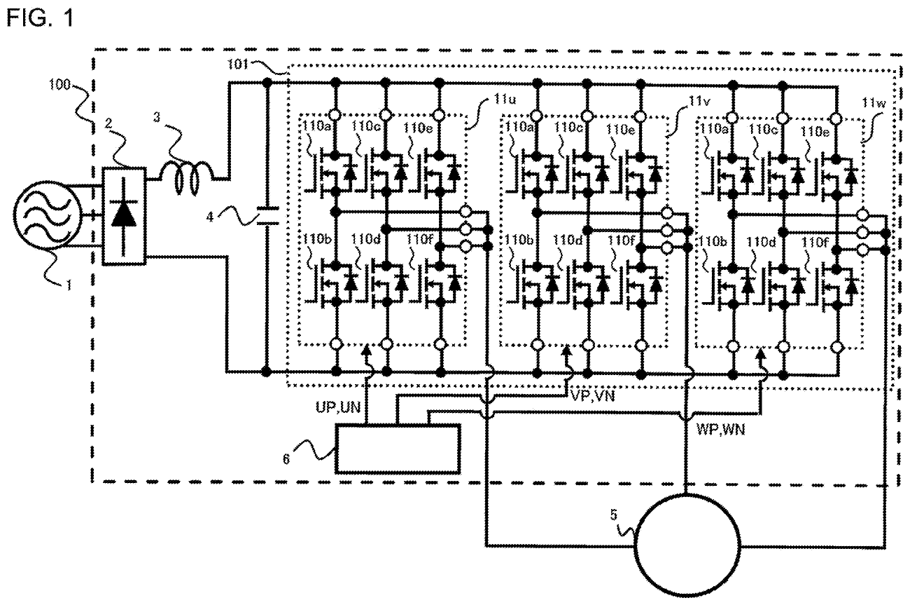

FIG. 1 is a diagram illustrating the overall configuration of a power conversion device according to Embodiment 1 of the present disclosure. For the sake of simplicity, a cooling plate to be described below has been omitted from FIG. 1. As illustrated in FIG. 1, a power conversion device 100 according to Embodiment 1 has a rectifier module 2, a reactor 3, a capacitor 4, and an inverter unit 101. The rectifier module 2 is, for example, some diode bridge that rectifies an alternating current input from an alternating-current power supply 1 to a direct current and is bridge-connected by using six backflow preventers for rectification. The inverter unit 101 converts the direct current output from the rectifier module 2 and input via the reactor 3 into a three-phase alternating current and drives an electric motor 5. The reactor 3 and the capacitor 4 are included in the power conversion device 100 in Embodiment 1, but are not limited to this configuration. The reactor 3 and the capacitor 4 may be externally attached to the power conversion device 100.

The inverter unit 101 is controlled by a controller 6. In FIG. 1, the controller 6 is provided outside the inverter unit 101, but is not limited to this configuration. The controller 6 may be provided inside the inverter unit 101. Furthermore, a voltage detector that detects voltages at opposite ends of the capacitor 4 may be provided, a current detector that detects an output current of the inverter unit 101 may be provided between the inverter unit 101 and the electric motor 5, and signals detected by the voltage detector and the current detector may be input to the controller 6. With such a configuration, information required for the control of the inverter unit 101 for driving the electric motor 5 can be obtained.

The inverter unit 101 includes an inverter module 11u corresponding to the u phase, an inverter module 11v corresponding to the v phase, and an inverter module 11w corresponding to the w phase. These inverter modules are, for example, power modules, such as intelligent power modules, that is, IPMs.

In the following description, the inverter module 11u, the inverter module 11v, and the inverter module 11w may sometimes be collectively referred to as inverter modules 11. Furthermore, in the following description, the rectifier module 2 and the inverter module 11u, the inverter module 11v, and the inverter module 11w of the inverter unit 101 may sometimes be collectively and simply referred to as modules.

The inverter module 11u includes a switching element 110a, a switching element 110b, a switching element 110c, a switching element 110d, a switching element 110e, and a switching element 110f. Likewise, the inverter module 11v includes a switching element 110a, a switching element 110b, a switching element 110c, a switching element 110d, a switching element 110e, and a switching element 110f. Similarly, the inverter module 11w includes a switching element 110a, a switching element 110b, a switching element 110c, a switching element 110d, a switching element 110e, and a switching element 110f.

In the inverter module 11u, the switching element 110a, the switching element 110c, and the switching element 110e constitute an upper arm. Moreover, in the inverter module 11u, the switching element 110b, the switching element 110d, and the switching element 110f constitute a lower arm. In the inverter module 11u, the switching element 110a and the switching element 110b are connected in series and constitute a switching element pair. Moreover, the switching element 110c and the switching element 110d are connected in series and constitute a switching element pair. Furthermore, the switching element 110e and the switching element 110f are connected in series and constitute a switching element pair. In other words, the inverter module 11u has three switching element pairs. The three switching element pairs are connected in parallel. The inverter module 11v and the inverter module 11w also have a configuration similar to the configuration of the inverter module 11u.

In the following description, the switching element 110a, the switching element 110b, the switching element 110c, the switching element 110d, the switching element 110e, and the switching element 110f may sometimes be collectively referred to as switching elements 110.

In FIG. 1, terminals connected to positive-electrode-side buses of the switching element 110a, the switching element 110c, and the switching element 110e at the upper arm are provided for the individual switching elements. Furthermore, terminals connected to negative-electrode-side buses of the switching element 110b, the switching element 110d, and the switching element 110f at the lower arm are also provided for the individual switching elements. However, the configuration is not limited to this description. Each of the positive-electrode terminals and the negative-electrode terminals may be grouped into a single terminal. The positive-electrode terminals may be grouped together into a single terminal for the switching element 110a, the switching element 110c, and the switching element 110e at the upper arm, and the negative-electrode terminals may be grouped together into a single terminal for the switching element 110b, the switching element 110d, and the switching element 110f at the lower arm.

In Embodiment 1, the switching elements 110 are arranged in parallel in the above-described configuration in each of the phases of the inverter module 11u, the inverter module 11v, and the inverter module 11w. Thus, even in a case where the current carrying capacity of each switching element 110 is low, a high current carrying capacity can be achieved in the entire inverter unit 101.

As described above, the controller 6 controls the inverter unit 101. Specifically, for each upper arm in each of the phases of the inverter modules 11 and for each lower arm in each of the phases of the inverter modules 11, the controller 6 generates a pulse width modulation (PWM) signal for controlling the on-off modes of the switching elements 110 and outputs the PWM signal to the inverter unit 101. The PWM signal is a pulsed signal having either an on or off value.

A PWM signal UP is a PWM signal for controlling the on-off modes of the switching element 110a, the switching element 110c, and the switching element 110e at the upper arm of the u-phase inverter module 11u. A PWM signal VP is a PWM signal for controlling the on-off modes of the switching element 110a, the switching element 110c, and the switching element 110e at the upper arm of the v-phase inverter module 11v. A PWM signal WP is a PWM signal for controlling the on-off modes of the switching element 110a, the switching element 110c, and the switching element 110e at the upper arm of the w-phase inverter module 11w.

A PWM signal UN is a PWM signal for controlling the on-off modes of the switching element 110b, the switching element 110d, and the switching element 110f at the lower arm of the u-phase inverter module 11u. A PWM signal VN is a PWM signal for controlling the on-off modes of the switching element 110b, the switching element 110d, and the switching element 110f at the lower arm of the v-phase inverter module 11v. A PWM signal WN is a PWM signal for controlling the on-off modes of the switching element 110b, the switching element 110d, and the switching element 110f at the lower arm of the w-phase inverter module 11w.

As will be described later, some inverter that converts a direct current into a three-phase alternating current is constituted of a pair of upper and lower arm switching elements per phase. In contrast, the inverter unit 101 according to Embodiment 1 is constituted of three pairs of upper and lower arm switching elements per phase. The controller 6 generates PWM signals through recognition that the three pairs of upper and lower arm switching elements as one set of upper and lower arm switching elements having a high current carrying capacity.

Furthermore, for each phase, that is, for each of the inverter modules 11u, 11v, and 11w, the controller 6 generates PWM signals for PWM-driving the switching elements 110a, 110b, 110c, 110d, 110e, and 110f. Specifically, the PWM signal UP and the PWM signal UN are each duplicated into three signals, and the duplicated signals are output to the inverter module 11u corresponding to the u phase. The PWM signal VP and the PWM signal VN are each duplicated into three signals, and the duplicated signals are output to the inverter module 11v corresponding to the v phase. The PWM signal WP and the PWM signal WN are each duplicated into three signals, and the duplicated signals are output to the inverter module 11w corresponding to the w phase.

Unbalanced current in each of the inverter modules 11u, 11v, and 11w may be prevented by performing a pulse-width adjustment on the duplicated PWM signals and outputting the pulse-width-adjusted signals to the inverter modules 11u, 11v, and 11w.

As an alternative to silicon (Si) commonly used for switching elements, wide-bandgap semiconductors, such as gallium nitride (GaN), silicon carbide (SiC), and diamond, may be used. The use of a wide-bandgap semiconductor achieves higher voltage endurance and a higher allowable current density, so that the inverter modules can be reduced in size. Moreover, as a wide-bandgap semiconductor has a lower heat value per unit area, as compared with Si, a maximum difference between the heat value of each inverter module 11 and the heat value of the rectifier module 2 can be reduced.

As a comparison with the inverter unit 101 according to Embodiment 1, a common inverter that drives a three-phase electric motor will be described. Generally, when a three-phase electric motor is to be driven by using an inverter, the inverter includes, for each phase, a switching element pair constituted of a single upper arm switching element and a single lower arm switching element that are connected in series. Therefore, a common inverter includes a total of three switching element pairs corresponding to the three phases, that is, six switching elements.

On the other hand, when switching elements are to be mounted as chips, the yield rate deteriorates when the chip area is increased. By reducing the chip area, the yield rate can be improved when the chips are taken out from a wafer. In particular, in a case where a wide-bandgap semiconductor is used for the switching elements, as wafers are expensive, it is desirable to reduce the chip area for achieving cost reduction.

However, a reduced chip area leads to a lower current carrying capacity, and it is thus difficult to achieve both cost reduction and a high current configuration with the inverter module in the related art that drives the three-phase electric motor by using the six switching elements. In contrast, in the inverter unit 101 according to Embodiment 1, the low-current-carrying-capacity switching elements 110 are arranged in parallel in each of the phases of the inverter module 11u, the inverter module 11v, and the inverter module 11w. For example, as the inverter modules 11 each include three switching element pairs, when the current carrying capacity of the mounted switching elements is defined as Am, the current carrying capacity of the inverter modules 11 is ideally 3×Am, and a high current carrying capacity can be thus achieved. Consequently, cost reduction and a high current configuration of the inverter unit 101 can both be achieved.

Furthermore, as illustrated in FIG. 1, the basic parts of the inverter modules 11u, 11v, and 11w, each constituted of six switching elements, of the inverter unit 101 can be standardized with a single type of three-phase inverter modules each constituted of six switching elements.

Therefore, as the inverter modules 11u, 11v, and 11w, the three-phase inverter modules each constituted of six switching elements can be used unchanged as the three-phase inverter modules are or can be used by adding a simple modification to the three-phase inverter modules. Specifically, it is not necessary to design and manufacture different types of inverter modules for the inverter module 11u, the inverter module 11v, and the inverter module 11w illustrated in FIG. 1. Therefore, the inverter module 11u, the inverter module 11v, and the inverter module 11w for a high current carrying capacity can be manufactured inexpensively.

For the sake of simplicity, the circuit diagram in FIG. 1 only illustrates main components of the inverter unit 101. Although there are various electric components and electronic components surrounding the inverter unit 101, such components have been omitted from FIG. 1.

Next, a method for cooling the rectifier module 2 and the inverter unit 101 in Embodiment 1 will be described.

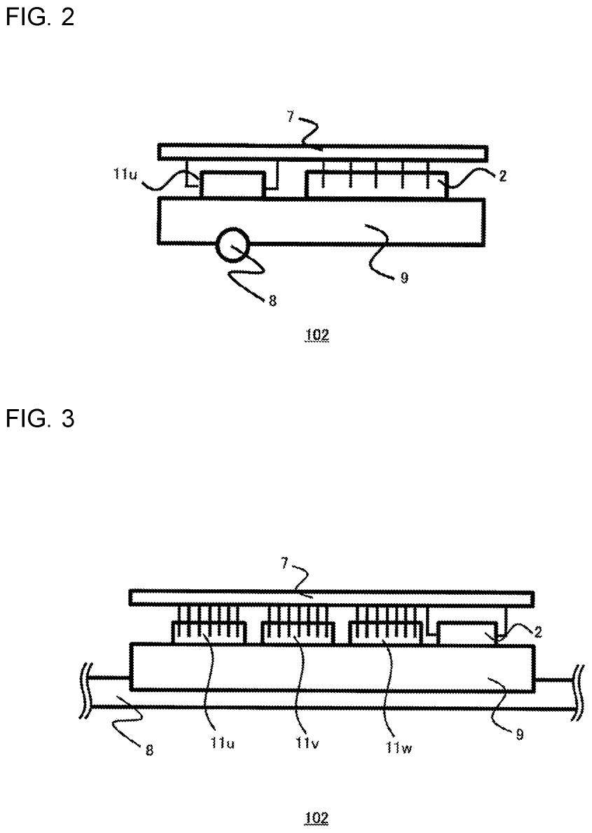

FIG. 2 and FIG. 3 are diagrams schematically illustrating a module cooling mechanism according to Embodiment 1 of the present disclosure. FIG. 2 and FIG. 3 are side views illustrating the positional relationships among a cooling plate 9 having a pipe 8 through which refrigerant in a refrigeration cycle flows, a substrate 7, and the rectifier module 2 and the inverter modules 11u, 11v, and 11w that are to be cooled by the cooling plate 9. FIG. 2 is a diagram as viewed from the short side of the substrate 7. FIG. 3 is a diagram as viewed from the long side of the substrate 7.

The refrigeration cycle for circulating the refrigerant includes a compressor, an expansion valve, and a heat exchanger that use some vapor compression refrigeration cycle, and uses the rotation of the electric motor 5 according to Embodiment 1 as a driving source for the compressor. A specific example of such a refrigeration cycle will be described later.

As illustrated in FIG. 2 and FIG. 3, with regard to the rectifier module 2 and the inverter modules 11u, 11v, and 11w, the terminals of each module, that is, for example, a pin and a lead, are electrically connected to the substrate 7. The substrate 7 has electric components and electronic components mounted on the substrate 7, such as a resistor and a capacitor (not illustrated), required for the configuration of the power conversion device 100 in FIG. 1.

As illustrated in FIG. 2 and FIG. 3, a cooling mechanism 102 has the pipe 8 and the cooling plate 9. The cooling plate 9 is made of, for example, metal, such as copper or aluminum. The pipe 8 is made of, for example, metal, such as copper or aluminum. The pipe 8 is a pipe to which the compressor that receives electric power from the power conversion device 100 is connected as a component. In addition to the compressor, the expansion valve, the heat exchanger, and other components are sequentially connected by the pipe 8, and the refrigeration cycle is thus formed. The pipe 8 has the refrigerant flowing through the pipe 8. The pipe 8 is attached to the inside of the cooling plate 9, or to the outer face of the cooling plate 9 in direct contact with the cooling plate 9 by, for example, brazing. Alternatively, the pipe 8 may be attached to the cooling plate 9 in indirect contact with the cooling plate 9 by interposing, for example, a seal between the pipe 8 and the cooling plate 9. Although FIG. 2 and FIG. 3 illustrate a configuration in which a single pipe 8 is attached to the cooling plate 9 having a cuboid shape, this configuration is merely an example, and the configuration is not limited to the configuration illustrated in FIG. 2 and FIG. 3.

The rectifier module 2 and the inverter modules 11u, 11v, and 11w are attached in such a manner that a heat dissipation face of each module and the cooling plate 9 are in contact with each other. The heat dissipation face and the cooling plate 9 may be indirectly in contact with each other by interposing a heat dissipation material, such as thermal grease, between the heat dissipation face and the cooling plate 9. The number of terminals of each module in FIG. 2 and FIG. 3 is an example, and FIG. 2 and FIG. 3 do not necessarily represent the exact number of terminals.

When the refrigerant flows through the pipe 8 attached to the cooling plate 9, the heat generated by each of the rectifier module 2, the inverter module 11u, the inverter module 11v, and the inverter module 11w is transferred to the refrigerant in the pipe 8 via the cooling plate 9. In other words, the refrigerant flowing through the pipe 8 is a module cooling medium.

With regard to the direction in which the substrate 7 is disposed, although the substrate 7 is disposed above the cooling plate 9 in Embodiment 1, as illustrated in FIG. 2 and FIG. 3, the configuration is not limited to this description. Depending on limitations on a housing to which the substrate 7 is attached, the face on which the pipe 8 is attached may be oriented upward, or the substrate 7 and the cooling plate 9 may be disposed perpendicularly to the floor surface.

Depending on the operating conditions of each module, a large difference lies between the heat value of each of the inverter modules 11u, 11v, and 11w and the heat value of the rectifier module 2, and subcooling and insufficient cooling performance may be caused. It is thus difficult to appropriately manage the temperature of each module. When the temperature of each module is not appropriately managed, the rectifier module 2 may possibly decrease in insulation properties or fail because of condensation occurring from subcooling, or a thermal failure of the inverter modules 11u, 11v, and 11w may possibly occur because of insufficient cooling.

In Embodiment 1, the thermal resistance between each of the inverter modules 11u, 11v, and 11w and the cooling plate 9 is different from the thermal resistance between the rectifier module 2 and the cooling plate 9. By making the thermal resistances different in this manner, subcooling and insufficient cooling performance caused by differences in heat values among the modules, particularly, a difference in heat values between the rectifier module 2 and each of the inverter modules 11u, 11v, and 11w, is prevented or reduced.

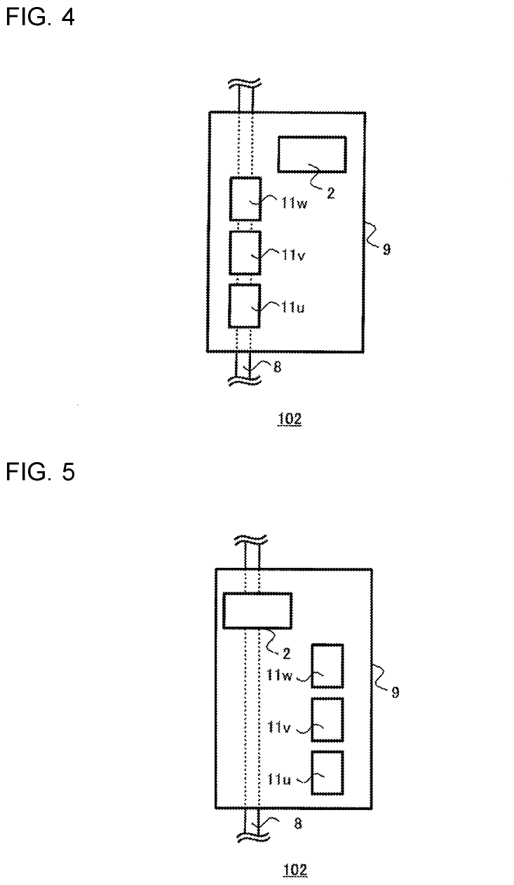

FIG. 4 and FIG. 5 illustrate the positional relationships among the modules on the cooling plate according to Embodiment 1 of the present disclosure. The aforementioned configuration in which the thermal resistance between one of the modules and the cooling plate 9 is different from the thermal resistance between another one of the modules and the cooling plate 9 will be described with reference to FIG. 4 and FIG. 5. FIG. 4 and FIG. 5 are plan views illustrating the positional relationships among the rectifier module 2 and the inverter modules 11u, 11v, and 11w that are in contact with the cooling plate 9, as viewed from a space that the substrate 7 faces. FIG. 4 illustrates an example of the positional relationships in a case where Si is used for the switching elements 110 of the inverter modules 11u, 11v, and 11w. FIG. 5 illustrates an example of the positional relationships in a case where a wide-bandgap semiconductor is used for the switching elements 110 of the inverter modules 11u, 11v, and 11w. In FIG. 4 and FIG. 5, the substrate 7 has been omitted.

Even when a power input to the power conversion device 100 in FIG. 1 is low, in a case where Si is used for the switching elements 110, the current output from the inverter modules 11u, 11v, and 11w is high, and the heat values of the inverter modules 11u, 11v, and 11w are thus caused to increase. In this case, the heat value of the rectifier module 2 is smaller than the heat value of each of the inverter modules 11u, 11v, and 11w. Therefore, the heat generated by each of the inverter modules 11u, 11v, and 11w has to be transferred efficiently to the refrigerant in the pipe 8. On the other hand, subcooling of the rectifier module 2 has to be avoided. As illustrated in FIG. 4, the inverter modules 11u, 11v, and 11w are disposed in a region on the cooling plate 9 where the inverter modules 11u, 11v, and 11w overlap the pipe 8 in a plan view of the cooling mechanism 102. Moreover, the rectifier module 2 is disposed in a region on the cooling plate 9 where the rectifier module 2 does not overlap the pipe 8 in a plan view of the cooling mechanism 102. In other words, the inverter modules 11 are disposed directly above or directly below the pipe 8 with the cooling plate 9 interposed between the inverter modules 11 and the pipe 8.

With the arrangement in FIG. 4, the distance between each inverter module 11 and the pipe 8 can be made shorter than the distance between the rectifier module 2 and the pipe 8. Thus, the thermal resistance between each of the inverter modules 11u, 11v, and 11w and the cooling plate 9 is lower than the thermal resistance between the rectifier module 2 and the cooling plate 9, so that the amount of heat transferred by each of the inverter modules 11u, 11v, and 11w is larger than the amount of heat transferred by the rectifier module 2. As a result, insufficient cooling of the inverter modules 11v and 11w is prevented or reduced. In addition, subcooling of the rectifier module 2 is prevented or reduced, and the occurrence of condensation around the rectifier module 2 is prevented.

When a wide-bandgap semiconductor is used for the switching elements 110 of the inverter modules 11u, 11v, and 11w, the heat value per unit area is reduced, as compared with the case where Si is used. Therefore, the magnitude relationship between the heat values of the inverter modules 11u, 11v, and 11w and the heat value of the rectifier module 2 may sometimes become inverted. In this case, contrary to the above-described case where Si is used for the switching elements 110, there is a possibility that the inverter modules 11u, 11v, and 11w may be subcooled and that the heat generated by the rectifier module 2 is not efficiently transferred to the pipe 8.

As illustrated in FIG. 5, in a case where a wide-bandgap semiconductor is used for the switching elements 110, the rectifier module 2 is disposed in a region on the cooling plate 9 where the rectifier module 2 overlaps the pipe 8 in a plan view of the cooling mechanism 102. Moreover, the inverter modules 11u, 11v, and 11w are disposed in a region on the cooling plate 9 where the inverter modules 11u, 11v, and 11w do not overlap the pipe 8 in a plan view of the cooling mechanism 102. In other words, the rectifier module 2 is disposed directly above or directly below the pipe 8 with the cooling plate 9 interposed between the rectifier module 2 and the pipe 8.

With the arrangement in FIG. 5, the distance between the rectifier module 2 and the pipe 8 can be made shorter than the distance between each inverter module 11 and the pipe 8. Thus, the thermal resistance between each of the inverter modules 11u, 11v, and 11w and the cooling plate 9 is higher than the thermal resistance between the rectifier module 2 and the cooling plate 9. Specifically, the magnitude relationship between the thermal resistance between each of the inverter modules 11u, 11v, and 11w and the cooling plate 9 and the thermal resistance between the rectifier module 2 and the cooling plate 9 is inverted from the case where Si is used for the switching elements 110. Therefore, the amount of heat transferred by each of the inverter modules 11u, 11v, and 11w is smaller than the amount of heat transferred by the rectifier module 2. As a result, subcooling of the inverter modules 11u, 11v, and 11w is prevented or reduced, and the occurrence of condensation around the inverter modules 11u, 11v, and 11w is prevented. In addition, insufficient cooling of the rectifier module 2 is prevented or reduced.

As described above, in the configuration where the above-described modules are cooled by being brought into contact with the cooling plate 9 provided with the pipe 8 to obtain the cooling performance required for achieving a high current carrying capacity of the inverter unit 101, appropriate cooling can be performed for each configuration of the inverter modules 11. Specifically, in a case where Si is used for each of the switching elements 110 of the inverter modules 11, insufficient cooling of the inverter modules 11 can be prevented, and condensation around the rectifier module 2 can be prevented or reduced. In a case where the switching elements 110 of the inverter modules 11 are each a wide-bandgap semiconductor, insufficient cooling of the rectifier module 2 can be prevented, and condensation around the inverter modules 11 can be prevented or reduced.

As mentioned above, the substrate 7 has electric components and electronic components mounted on the substrate 7, such as a resistor and a capacitor, required for the configuration of the power conversion device 100. The electric components and the electronic components receive heat from the inverter modules 11 and the rectifier module 2 mounted on the substrate 7 via wires on the substrate 7. Some component, such as an electrolytic capacitor, mounted on the substrate 7 may deteriorate in performance or may decrease in component lifespan when the component reaches a high temperature. When a high-current inverter unit 101 is constituted by using a single inverter module, heat generating sections are concentrated in a region including the location where the inverter module is disposed, and cooling properties for electric components and electronic components mounted in a region including the location where the inverter module is disposed are thus reduced. Such reduced cooling properties result in deteriorated performance and shortened component lifespan of the electric components and the electronic components mounted in the region including the location where the inverter module is disposed. When such deteriorated performance and such shortened component lifespan of the electric components and the electronic components are to be avoided, electric components and electronic components with temperature constraints cannot be disposed close to the inverter module, and the circuit design of the substrate 7 is thus limited.

As the inverter unit 101 is constituted by using a plurality of inverter modules 11u, 11v, and 11w in Embodiment 1, the heat generating sections on the substrate 7 are disposed in a distributed manner. Therefore, the cooling properties for the electric components and the electronic components mounted close to the inverter modules 11 are prevented from being impaired, and positional limitations and circuit design limitations on electric components and electronic components with temperature constraints are alleviated.

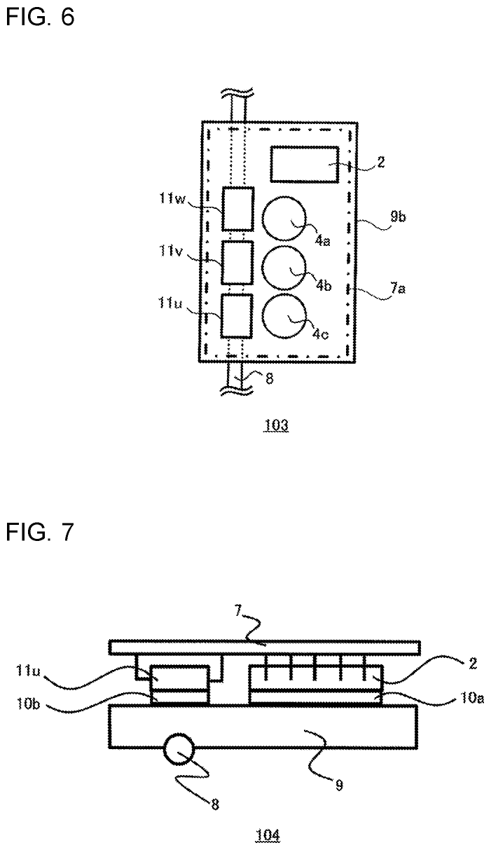

FIG. 6 is a diagram illustrating a cooling structure for modules and capacitors in the power conversion device according to Embodiment 1 of the present disclosure. In FIG. 6, the arrangement of modules in a module cooling mechanism 103 is illustrated together with the arrangement of capacitors. In FIG. 6, a substrate 7a is similar to the substrate 7 illustrated in FIG. 2 and FIG. 3, and a cooling plate 9b is similar to the cooling plate 9 illustrated in FIG. 2 to FIG. 4. In FIG. 6, components similar to the components in FIG. 2 to FIG. 5 are given the same reference signs. FIG. 6 is a schematic diagram in which the arrangement of the substrate 7a and a capacitor 4a, a capacitor 4b, and a capacitor 4c has been added to a schematic diagram illustrating the positional relationships among the rectifier module 2 and the inverter modules 11u, 11v, and 11w that are in contact with the cooling plate 9b.

In FIG. 6, the substrate 7a is denoted by a single-dot chain line. The rectifier module 2, the inverter module 11u, the inverter module 11v, and the inverter module 11w are mounted on the substrate 7a toward the back of the plane of the drawing. The capacitor 4a, the capacitor 4b, and the capacitor 4c are mounted on the substrate 7a toward the front of the plane of the drawing. The manner in which the rectifier module 2, the inverter module 11u, the inverter module 11v, and the inverter module 11w are mounted on the substrate 7a and the manner in which the capacitor 4a, the capacitor 4b, and the capacitor 4c are mounted on the substrate 7a are merely examples. Furthermore, although the number of capacitors is three as an example, the number of capacitors is not limited to three. Moreover, although the substrate 7a and the cooling plate 9b have different planar sizes, the sizes of the substrate 7a and a cooling plate 9a are appropriately designed to correspond to limitations on a housing to which the substrate 7a is attached, and the dimensional relationship between the substrate 7a and the cooling plate 9b has no relation to the dimensional relationship described in Embodiment 1.

As illustrated in FIG. 6, the inverter modules 11u, 11v, and 11w are mounted in a region on the cooling plate 9b where the inverter modules 11u, 11v, and 11w overlap the pipe 8 in a plan view of the module cooling mechanism 103. The capacitors 4a, 4b, and 4c are mounted on the cooling plate 9b at positions close to the inverter modules 11u, 11v, and 11w. Therefore, the capacitors 4a, 4b, and 4c can be cooled by cold air from the cooling plate 9b. As a result, in addition to the above-described advantage in which the inverter modules 11, which are heat generating sections, are disposed in a distributed manner on the substrate 7a, an advantage of improved cooling performance for the capacitors 4a, 4b, and 4c, which are electronic components with temperature constraints, can be achieved.

Furthermore, to prevent condensation, waterproof sheets made of an insulating material may be adhered around areas where the rectifier module 2 and the inverter modules 11u, 11v, and 11w are in contact with the cooling plate 9b. Adhesion of such waterproof sheets not only improves waterproofness but also improves the insulation properties, so that an advantage of improved surge resistance can also be achieved.

According to Embodiment 1, in a case where the inverter unit 101 that is cooled by exchanging heat with the refrigerant flowing through the pipe 8 via the cooling plate 9 having the pipe 8 of the refrigeration cycle is constituted by using a plurality of inverter modules, the following advantage is achieved. The advantage is such that condensation caused by subcooling of the inverter modules 11 of the inverter unit 101 and the rectifier module 2 can be prevented or reduced, and the inverter modules 11 and the rectifier module 2 can be cooled to a desired temperature range in which a thermal failure does not occur. This advantage is prominent especially under a condition in which a difference in heat values between the rectifier module 2 and each of the inverter modules 11 is large.

### Embodiment 2

Next, a power conversion device according to Embodiment 2 of the present disclosure will be described. In Embodiment 2, unique features different from the features described in Embodiment 1 above will be described, and descriptions of features identical or equivalent to the features described in Embodiment 1 will be omitted, where appropriate, as the description of Embodiment 1 above is referable.

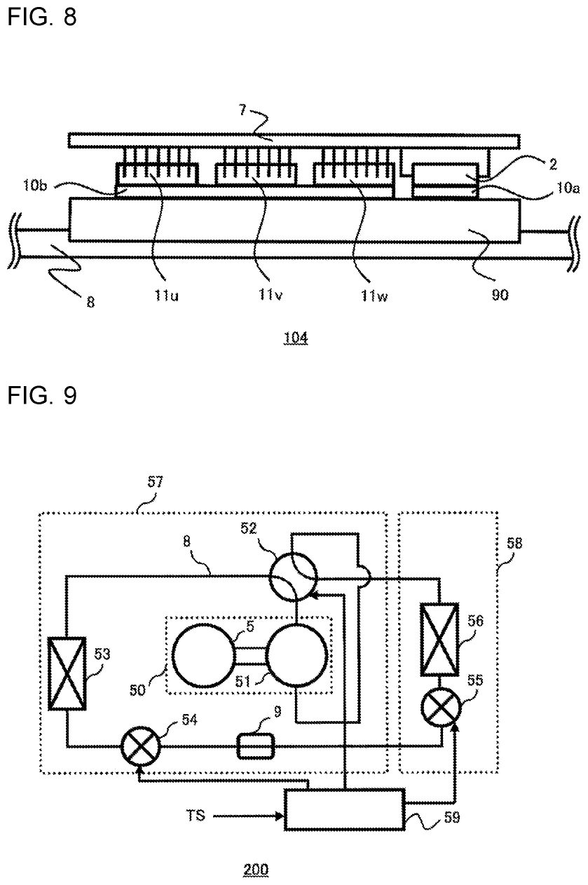

FIG. 7 and FIG. 8 are diagrams schematically illustrating a module cooling mechanism according to Embodiment 2 of the present disclosure. With regard to a cooling mechanism 104 according to Embodiment 2, a configuration having a correction plate 10a between the rectifier module 2 and the cooling plate 9 according to Embodiment 1 above and having a correction plate 10b between the inverter modules 11u, 11v, and 11w and the cooling plate 9 according to Embodiment 1 above will be described. The correction plate 10a and the correction plate 10b are components for adjusting the distance between the inverter modules 11u, 11v, and 11w and the cooling plate 9.

When small-size inverter modules 11u, 11v, and 11w are to be used or a small-size rectifier module 2 is to be used, it is difficult to ensure an insulation distance between the terminals of each module, that is, for example, a pin and a lead, and the cooling plate 9. Unless an insulation distance is ensured, when an excessive voltage is applied to these modules because of, for example, lightning, a surge occurs between the terminals of each module and the cooling plate 9, and a failure of these modules may be thus caused.

The correction plates 10a and 10b are inserted each between the cooling plate 9 and the at least corresponding one of the rectifier module 2 and the inverter modules 11u, 11v, and 11w. The correction plates 10a and 10b are for adjusting the distances each between the cooling plate 9 and the at least corresponding one of the rectifier module 2 and the inverter modules 11u, 11v, and 11w. Accordingly, an insulation distance can be ensured between the terminals of each module and the cooling plate 9.

FIG. 7 and FIG. 8 are side views illustrating the positional relationships among the cooling plate 9 having the pipe 8 through which the refrigerant in the refrigeration cycle flows, the substrate 7, the correction plate 10a, the correction plate 10b, the rectifier module 2, and the inverter modules. The rectifier module 2 and the inverter modules are similar to the rectifier module 2 and the inverter modules in Embodiment 1 in that the rectifier module 2 and the inverter modules are cooled by the cooling plate 9. FIG. 7 is a diagram as viewed from a short side of the substrate 7. FIG. 8 is a diagram as viewed from a long side of the substrate 7. The correction plate 10a is inserted between the rectifier module 2 and the cooling plate 9, and the correction plate 10b is inserted between the inverter modules 11u, 11v, and 11w and the cooling plate 9.

In the cooling mechanism 104, the correction plate 10a and the correction plate 10b do not necessarily have to be made of the same type of metal as the metal of the cooling plate 9. However, to ensure the same thermal conductivity as the thermal conductivity of the cooling plate 9 and to prevent corrosion between different types of metal, it is desirable that the correction plate 10a and the correction plate 10b be made of the same type of metal as the metal of the cooling plate 9.

However, it is not necessarily required to insert both the correction plate 10a and the correction plate 10b. A correction plate may be inserted into only a region between the cooling plate 9 and a module that is difficult to ensure the insulation distance between the terminal of the module and the cooling plate 9. The height of the correction plates does not have to be the same for the correction plate 10a and the correction plate 10b. The height may be adjusted in such a manner that the insulation distance can be ensured to correspond to the size of each module.

The rectifier module 2 and the inverter modules 11u, 11v, and 11w are attached in such a manner that a heat dissipation face of each module and the corresponding one of the faces of each of the correction plate 10a and the correction plate 10b are in contact with each other. Moreover, the rectifier module 2 and the inverter modules 11u, 11v, and 11w are attached in such a manner that the other face of each of the correction plates 10a and 10b, that is, the face opposite the aforementioned contact face, and the cooling plate 9 are in contact with each other. The heat dissipation face of each module and the corresponding one of the faces of each of the correction plate 10a and the correction plate 10b may be indirectly in contact with each other by interposing a heat dissipation material, such as thermal grease, between the heat dissipation face and the corresponding one of the faces, and moreover, the other face of each of the correction plate 10a and the correction plate 10b and the cooling plate 9 may be indirectly in contact with each other by interposing a heat dissipation material, such as thermal grease, between the other face and the cooling plate 9. The number of terminals in each module in FIG. 7 and FIG. 8 is an example, and FIG. 7 and FIG. 8 do not necessarily represent the exact number of terminals.

The correction plates 10a and 10b and the cooling plate 9 do not necessarily have to be separate components, and may be constituted of a single metallic component, so long as the aforementioned object can be achieved. Specifically, sections of the cooling plate 9 that are in contact with the modules may be each formed into a protruding shape. In other words, the face of the cooling plate 9 onto which the modules are to be disposed may have protrusions that are in contact with the modules. With this configuration, the cooling plate 9 can be formed by being cut from a single metallic mass, and the need is thus eliminated for performing working steps, such as a step for applying a heat dissipation material and a step for positioning the correction plate 10a and the correction plate 10b. Furthermore, the correction plate 10a and the correction plate 10b may be a single metallic component and may be a single plate. Accordingly, the number of components can be reduced, and the number of positioning steps can be reduced.

As described above, in Embodiment 2, the following advantage is achieved, in addition to the advantages of Embodiment 1. Specifically, when an enormously high voltage is applied to the small-size inverter modules 11u, 11v, or 11w or the rectifier module 2, a surge occurring between the terminals of each module and the cooling plate 9 is prevented or reduced, so that an advantage of avoiding failures caused by such a surge can be achieved.

### Embodiment 3

Next, a power conversion device according to Embodiment 3 of the present disclosure will be described. In Embodiment 3, unique features different from the features described in Embodiment 1 and Embodiment 2 above will be described, and descriptions of features identical or equivalent to the features described in Embodiment 1 and Embodiment 2 will be omitted, where appropriate, as the descriptions of Embodiment 1 and Embodiment 2 above are referable.

In Embodiment 3, the configuration of the refrigeration cycle for circulating the refrigerant and the control of the refrigerant will be described. The control of the refrigerant according to Embodiment 3 is for appropriately cooling the rectifier module 2 and the inverter unit 101 by using the cooling plate 9 having the pipe 8 through which the refrigerant flows, described in Embodiment 1 and Embodiment 2. Needless to say, the correction plate 10a and the correction plate 10b described above may be used. However, the following description relates to a configuration in which the correction plate 10a and the correction plate 10b are not used. First, a refrigerant circuit included in the refrigeration cycle will be described.

FIG. 9 is a diagram illustrating the configuration of a refrigerant circuit according to Embodiment 3 of the present disclosure. FIG. 9 illustrates an example of the configuration of the refrigerant circuit having a compressor 50 that compresses the refrigerant by using the rotation of the electric motor 5 as a driving source. An air-conditioning apparatus 200 has an outdoor unit 57 and an indoor unit 58. The outdoor unit 57 has the compressor 50, a four-way valve 52, a heat-source-side heat exchanger 53, and a heat-source-side expansion valve 54. Although not illustrated in FIG. 9, an accumulator that stores excess refrigerant may be provided to a suction portion of the compressor 50. The indoor unit 58 has a load-side expansion valve 55 and a load-side heat exchanger 56. Additionally, the air-conditioning apparatus 200 has an air-conditioning controller 59 that controls the four-way valve 52, the heat-source-side expansion valve 54, and the load-side expansion valve 55. In FIG. 9, the air-conditioning controller 59 is configured to receive information of a temperature detected by a temperature detector to be described below. In FIG. 9, the temperature detected by the temperature detector is denoted by TS.

The refrigerant circuit according to Embodiment 3 includes the compressor 50, the four-way valve 52, the heat-source-side heat exchanger 53, the heat-source-side expansion valve 54, the load-side expansion valve 55, and the load-side heat exchanger 56 that are sequentially connected by the pipe 8. The refrigerant is caused to flow through this refrigerant circuit so that a refrigeration cycle is established. Furthermore, the cooling plate 9 is attached to the pipe 8 of the refrigerant circuit. For example, the cooling plate 9 is disposed between the heat-source-side expansion valve 54 and the load-side expansion valve 55.

As shown in FIG. 9, the refrigerant circuit included in the refrigeration cycle according to Embodiment 3 is configured in such a manner that the heat-source-side heat exchanger 53, the heat-source-side expansion valve 54, the load-side expansion valve 55, the load-side heat exchanger 56, and the compressor 50 are arranged in series. The refrigerant circuit included in the refrigeration cycle in FIG. 9 is merely an example and is not limited to this configuration.

The compressor 50 has the electric motor 5 and a compression element 51 driven by the electric motor 5, and compresses the refrigerant flowing through the pipe 8. As described above with reference to FIG. 1, the controller 6 controls the inverter unit 101, so that the voltage and the frequency, that is, the rotation speed, of the electric motor 5 are controlled. The compression element 51 compresses suctioned low-temperature low-pressure refrigerant into high-temperature high-pressure refrigerant.

The heat-source-side expansion valve 54 and the load-side expansion valve 55 are expansion valves, such as linear expansion valves (LEVs), that is, linear electronic expansion valves, and reduce the pressure of the refrigerant. The heat-source-side heat exchanger 53 exchanges heat between outside air and the refrigerant. The heat-source-side heat exchanger 53 is used as a condenser during cooling operation, and is used as an evaporator during heating operation. The load-side heat exchanger 56 exchanges heat between air in an air-conditioned space and the refrigerant. The load-side heat exchanger 56 is used as an evaporator during cooling operation, and is used as a condenser during heating operation. The four-way valve 52 changes the flow path of the refrigerant.

The refrigerant circuit included in the refrigeration cycle for circulating the refrigerant has been described above. The following description relates to refrigerant control in Embodiment 3 for cooling the rectifier module 2 and the inverter unit 101 by using the cooling plate 9.

The refrigerant control involves adjusting the opening degree of at least one of the heat-source-side expansion valve 54 and the load-side expansion valve 55 to adjust the flow rate of refrigerant flowing through the pipe 8 so that the rectifier module 2 and the inverter modules 11 of the inverter unit 101 are within a desired temperature range. The flow rate of refrigerant is adjusted in this manner so that the cooling performance for the rectifier module 2 and the inverter modules 11u, 11v, and 11w of the inverter unit 101 is adjusted. The desired temperature range is a temperature range in which a thermal failure does not occur and in which condensation does not occur around the modules. The heat-source-side expansion valve 54 and the load-side expansion valve 55 may be controlled through additionally providing the air-conditioning controller 59 used as a controller for the refrigerant circuit, as illustrated in FIG. 9. Alternatively, the function for controlling the heat-source-side expansion valve 54 and the load-side expansion valve 55 may be integrated in the controller 6 that controls the inverter unit 101, and the controller 6 may control the heat-source-side expansion valve 54 and the load-side expansion valve 55.

An example of the control of the heat-source-side expansion valve 54 and the load-side expansion valve 55 will be described below. A first threshold value T1 is set as a module temperature at which condensation does not occur from surroundings of the module cooled by the module temperature that is lower than the outside air temperature, and a second threshold value T2 is set as a module temperature at which a thermal failure does not occur from the module temperature exceeding its limit temperature. When the module temperature becomes higher than the second threshold value T2, at least one of the heat-source-side expansion valve 54 and the load-side expansion valve 55 is opened. When the module temperature becomes lower than the first threshold value T1, at least one of the heat-source-side expansion valve 54 and the load-side expansion valve 55 is closed. When the module temperature is between the first threshold value T1 and the second threshold value T2, at least one of the heat-source-side expansion valve 54 and the load-side expansion valve 55 is intermittently controlled to be opened and closed. From a viewpoint of a heat cycle, it is desirable that the module temperature be fixed to maintain the performance of the module until its lifespan. The heat-source-side expansion valve 54 and the load-side expansion valve 55 are controlled in the above-described manner so that the module temperature can be kept within a range in which the lower limit slightly fluctuates from the first threshold value T1 and the upper limit slightly fluctuates from the second threshold value T2. Consequently, the performance of the module can be maintained until its lifespan.

The first threshold value T1 is only required to be set to the outside air temperature, and the second threshold value T2 is only required to be set to the limit temperature of the module. Furthermore, it is more desirable that the first threshold value T1 be set high enough to have a margin from the outside air temperature, and that the second threshold value T2 be set low enough to have a margin from the limit temperature of the module that is the lowest among the limit temperatures of the rectifier module 2 and the inverter modules 11. This is because thermal transfer responsiveness is lower than electrical transfer responsiveness and also because it is difficult to control an expansion valve on the order of μs, as with a switching element of a power module. Therefore, the first threshold value T1 and the second threshold value T2 are set to have margins, and the reliability of module temperature protection is thus further improved.

With regard to the value of the outside air temperature required when the first threshold value T1 is to be set, the outside air temperature may be directly measured with, for example, a temperature sensor, or an estimated outside-air-temperature range may be simply obtained in advance by, for example, an analysis or actual measurement, and the maximum value of the estimated outside air temperature may be set as the first threshold value T1.

In Embodiment 3, the refrigerant control described above involves detecting the temperatures of all of the rectifier module 2 and the inverter unit 101, that is, the inverter modules 11u, 11v, and 11w, illustrated in FIG. 1 and performing the control on the basis of all of these temperatures. The control is only required to be performed in such a manner that the highest temperature among the temperatures of these modules is lower than or equal to the second threshold value T2 and the lowest temperature among the temperatures of these modules is higher than or equal to the first threshold value T1.

When control is to be performed by using a single common three-phase inverter module constituted of six switching elements, there is one temperature detection value to be input to the air-conditioning controller 59. The same applies to a case where the rectifier module 2 is provided in an inverter module. In contrast, in Embodiment 3, as the temperatures of all of the rectifier module 2 and the inverter modules 11u, 11v, and 11w are detected, there are four temperature detection values. Therefore, the air-conditioning controller 59 cannot be standardized between the case where the inverter module in the related art is used and the case where the inverter modules according to Embodiment 3 are used. Moreover, the specifications of the air-conditioning controller 59 have to be changed so that it can receive four temperature detection values, and also the specifications of, for example, a microcomputer included in the air-conditioning controller 59 thus have to be changed. Furthermore, in a case where a temperature detector is to be additionally provided for each of the rectifier module 2 and the inverter modules 11u, 11v, and 11w, four temperature detectors are necessary, and costs are thus caused to increase.

In Embodiment 3, only the temperature of the module that needs temperature management the most among the aforementioned four modules, namely, the rectifier module 2 and the inverter modules 11u, 11v, and 11w, may be detected. Then, the refrigerant control is performed by controlling opening and closing of the heat-source-side expansion valve 54 and the load-side expansion valve 55 in such a manner that the detected temperature is lower than or equal to the second threshold value T2 and higher than or equal to the first threshold value T1.

Among the aforementioned four modules, the inverter modules 11u, 11v, and 11w undergo switching control by the controller 6, so that the heat values can be controlled by an adjustment of switching operation having a correlation with the heat values.

For example, the rectifier module 2 is mainly some diode bridge bridge-connected by using six backflow preventers for rectification. Therefore, the heat value of the rectifier module 2 is dependent on the magnitude of input alternating-current power. In other words, the heat value of the rectifier module 2 is dependent on the magnitude of output direct-current power converted from input alternating-current power. Therefore, the heat value cannot be controlled at the rectifier module 2. Furthermore, when the load of the electric motor 5, that is, the load of the compressor 50, is small, the heat value of the rectifier module 2 is relatively small. When the load is large, the heat value of the rectifier module 2 is relatively large. The heat value of the rectifier module 2 changes greatly in this manner, and cooling has to be appropriately performed to correspond to changes in the heat value due to load fluctuations.

As described above, the need for temperature management of the rectifier module 2 is greater than the need for temperature management of the inverter modules 11. In Embodiment 3, a temperature detector, such as a temperature sensor and a thermistor, is attached to the rectifier module 2, and refrigerant control is performed on the basis of the temperature detected by this temperature detector, so that cooling of the rectifier module 2 is prioritized.

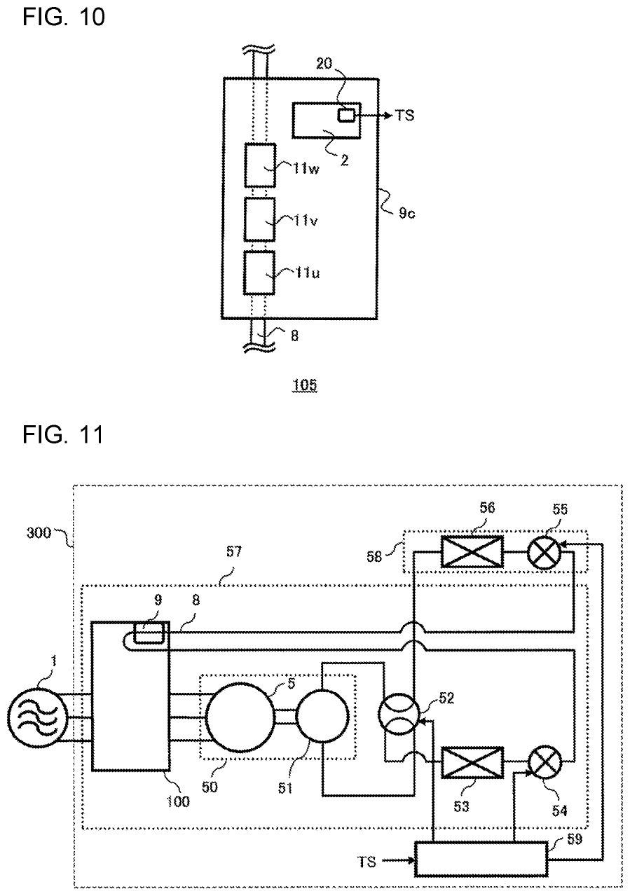

FIG. 10 is a diagram schematically illustrating a module cooling mechanism according to Embodiment 3 of the present disclosure. Similar to FIG. 4 to FIG. 6, FIG. 10 is a plan view illustrating the positional relationships among the rectifier module 2 and the inverter modules 11u, 11v, and 11w that are in contact with a cooling plate 9c, as viewed from the space that the substrate 7 faces. In FIG. 8, the substrate 7 has been omitted, and a temperature detector 20 is schematically illustrated. In a cooling mechanism 105, the temperature detector 20 is attached to the rectifier module 2. The temperature detector 20 is some temperature sensor or thermistor, as mentioned above, and the temperature of the rectifier module 2 is detected by the temperature detector 20.

A temperature TS detected by the temperature detector 20 is input to the air-conditioning controller 59 in FIG. 9 or to the controller 6 illustrated in FIG. 1. Then, the air-conditioning controller 59 or the controller 6 performs refrigerant control by controlling opening and closing of the heat-source-side expansion valve 54 and the load-side expansion valve 55 in such a manner that the temperature TS is lower than or equal to the second threshold value T2 and higher than or equal to the first threshold value T1.

However, the rectifier module 2 is often constituted of some diode bridge, as mentioned above. Normally, a diode bridge does not have a temperature detecting mechanism. Thus, when the rectifier module 2 is some diode bridge, it is necessary to attach the temperature detector 20 to the rectifier module 2, as illustrated in FIG. 10. On the other hand, some intelligent power modules, that is, IPMs, used as inverter modules contain temperature sensors, such as thermistors.

For these reasons, the temperature detected by the temperature sensor contained in the inverter module located closest to the rectifier module 2 among the inverter modules 11u, 11v, and 11w included in the inverter unit 101 may be used as the temperature of the rectifier module 2. For example, in the example illustrated in FIG. 4 and FIG. 5, the temperature detected by the temperature sensor contained in the inverter module 11w is used. Although this is simplified temperature detection, as compared with direct detection of the temperature of the rectifier module 2 using the temperature detector 20, an additional temperature detecting mechanism, such as a temperature sensor and a thermistor, does not have to be attached. This is advantageous in that the cost required for temperature detection can be reduced.

As described above, in Embodiment 3, condensation caused by subcooling of the rectifier module 2 can be prevented or reduced, all of the modules can be prevented from a thermal failure and can also be cooled to the predetermined temperature range, and the performance of each module can be thus maintained until its lifespan.

### Embodiment 4

Next, an air-conditioning apparatus according to Embodiment 4 of the present disclosure will be described. In Embodiment 4, unique features different from the features described in Embodiment 1, Embodiment 2, and Embodiment 3 above will be described, and descriptions of features identical or equivalent to the features described in Embodiment 1, Embodiment 2, and Embodiment 3 above will be omitted, where appropriate, as the descriptions of Embodiment 1, Embodiment 2, and Embodiment 3 above are referable.

In Embodiment 4 of the present disclosure, an example where the power conversion device 100 according to Embodiment 1 is applied to an air-conditioning apparatus will be described.

FIG. 11 is a diagram illustrating the configuration of an air-conditioning apparatus according to Embodiment 4 of the present disclosure. In FIG. 11, components similar to the components of the power conversion device 100 according to Embodiment 1 and Embodiment 2 and the air-conditioning apparatus 200 according to Embodiment 3 are given the same reference signs. Detailed descriptions of such components will be omitted.

In an air-conditioning apparatus 300, a refrigerant circuit is constituted similarly to the refrigerant circuit in the air-conditioning apparatus 200 according to Embodiment 3. Specifically, the refrigerant circuit includes the compressor 50, the four-way valve 52, the heat-source-side heat exchanger 53, the heat-source-side expansion valve 54, the load-side expansion valve 55, and the load-side heat exchanger 56 that are sequentially connected by the pipe 8. The refrigerant is caused to flow through this refrigerant circuit so that a refrigeration cycle is established. Although not illustrated in FIG. 11, an accumulator that stores excess refrigerant may be provided to the suction portion of the compressor 50. To control the refrigerant circuit, the air-conditioning controller 59 or the controller 6 of the power conversion device 100 illustrated in FIG. 1 controls the four-way valve 52, the heat-source-side expansion valve 54, and the load-side expansion valve 55 and receives information of the temperature TS detected by the temperature detector 20 illustrated in FIG. 10.

The configuration of the refrigeration cycle according to Embodiment 4 of the present disclosure is an example. The refrigeration cycle does not necessarily have to have the same configuration.

The operation of the air-conditioning apparatus 300 illustrated in FIG. 11 will be described below with reference to cooling operation as an example. In FIG. 11, when cooling operation is to be performed, the four-way valve 52 has changed the flow path in advance in such a manner that the refrigerant discharged from the compressor 50 travels toward the heat-source-side heat exchanger 53 and the refrigerant flowing out from the load-side heat exchanger 56 travels toward the compressor 50. Although a detailed description of heating operation will be omitted, heating operation can also be achieved by changing the flow path in the four-way valve 52 in such a manner that the refrigerant discharged from the compressor 50 travels toward the load-side heat exchanger 56 and the refrigerant flowing out from the heat-source-side heat exchanger 53 travels toward the compressor 50.

The power conversion device 100 drives the electric motor 5 so that the compression element 51 linked with the electric motor 5 compresses the refrigerant into high-temperature high-pressure refrigerant, and the compressor 50 discharges the high-temperature high-pressure refrigerant. The high-temperature high-pressure refrigerant discharged from the compressor 50 flows into the heat-source-side heat exchanger 53 via the four-way valve 52 and rejects heat by exchanging the heat with outside air at the heat-source-side heat exchanger 53.

The refrigerant flowing out from the heat-source-side heat exchanger 53 is expanded and reduced in pressure at the heat-source-side expansion valve 54 and flows into the cooling plate 9 as low-temperature low-pressure two-phase gas-liquid refrigerant. At the cooling plate 9, a portion of the liquid refrigerant in the two-phase gas-liquid refrigerant evaporates by receiving heat generated at the power conversion device 100.

The two-phase gas-liquid refrigerant flowing out from the cooling plate 9 is expanded and reduced in pressure at the load-side expansion valve 55, flows into the load-side heat exchanger 56, evaporates by exchanging heat with the air in the air-conditioned space, and flows out from the load-side heat exchanger 56 as low-temperature low-pressure refrigerant. The refrigerant flowing out from the load-side heat exchanger 56 is suctioned into the compressor 50 via the four-way valve 52 and is compressed again. The above operation is repeated.

In the configuration in FIG. 11, the indoor unit 58 includes the load-side expansion valve 55, and the outdoor unit 57 includes the heat-source-side expansion valve 54. In other words, the indoor unit 58 and the outdoor unit 57 are both provided with respective expansion valves. With this configuration, the cooling performance of each of the above-described modules of the power conversion device 100 can be controlled independently with the two expansion valves, namely, the heat-source-side expansion valve 54 and the load-side expansion valve 55. Such a configuration is suitable for finely controlling the refrigerant in such a manner that the temperature TS detected by the temperature detector 20 is lower than or equal to the second threshold value T2 and higher than or equal to the first threshold value T1. Therefore, the occurrence of condensation can be prevented without lowering the temperature of each module of the power conversion device 100 more than necessary, and control can be performed in such a manner that a thermal failure caused by an increased temperature is prevented.

The configuration in FIG. 11 is merely an example where the temperature of each module of the power conversion device 100 is finely controlled, and does not necessarily have to be provided with two expansion valves, namely, the heat-source-side expansion valve 54 and the load-side expansion valve 55. Specifically, at least one of the indoor unit 58 and the outdoor unit 57 may be provided with an expansion valve.

In Embodiment 4, the above-described power conversion device 100 according to Embodiment 1 and Embodiment 2 is applied to the air-conditioning apparatus 300. Specifically, in the inverter unit 101 that controls the electric motor 5 that drives the compressor 50 of the outdoor unit 57, the inverter modules 11 are connected in parallel. Thus, a high-current power conversion device 100 can be achieved at low cost. As a result, this is advantageous in that a high-capacity high-powered power conversion device 100 can be achieved at low cost.

Although an example where the above-described power conversion device 100 according to Embodiment 1 and Embodiment 2 is applied to the air-conditioning apparatus 300 is described in Embodiment 4, the application is not limited to this example. The power conversion device 100 may be applied to an apparatus having a refrigeration cycle, such as a heat pump apparatus and a refrigeration apparatus, as an alternative to the air-conditioning apparatus 300.

### REFERENCE SIGNS LIST

alternating-current power supply 2 rectifier module 3 reactor 4 capacitor 4a capacitor 4b capacitor 4c capacitor 5 electric motor 6 controller 7 substrate 7a substrate 8 pipe 9 cooling plate 9a cooling plate 9b cooling plate 9c cooling plate 10a correction plate 10b correction plate 11 inverter module 11u inverter module 11v inverter module 11w inverter module 20 temperature detector 50 compressor 51 compression element 52 four-way valve 53 heat-source-side heat exchanger heat-source-side expansion valve 55 load-side expansion valve 56 load-side heat exchanger 57 outdoor unit 58 indoor unit 59 air-conditioning controller 100 power conversion device 101 inverter unit 102 cooling mechanism 103 cooling mechanism 104 cooling mechanism 105 cooling mechanism 110 switching element 110a switching element 110b switching element 110c switching element 110d switching element 110e switching element 110f switching element 200 air-conditioning apparatus 300 air-conditioning apparatus

1. A power conversion device, comprising:
a rectifier module configured to rectify an alternating current supplied from an alternating-current power supply;
an inverter unit configured to convert a direct current rectified by the rectifier module into an alternating current, output the alternating current to an electric motor, and drive the electric motor, the inverter unit having a plurality of inverter modules; and
a cooling mechanism configured to cool the rectifier module and the plurality of inverter modules,
the cooling mechanism being configured in such a manner that thermal resistance between the rectifier module and the cooling mechanism is different from thermal resistance between the plurality of inverter modules and the cooling mechanism,
the cooling mechanism having
a pipe through which refrigerant flows, the refrigerant receiving heat generated by the rectifier module and heat generated by the plurality of inverter modules, and
a cooling plate to which the pipe is attached,
the cooling plate having a protrusion on a face of the cooling plate where the plurality of inverter modules are disposed, the protrusion being in contact with at least part of the plurality of inverter modules.

2. The power conversion device of claim 1,
wherein, in the cooling mechanism, among the plurality of inverter modules and the rectifier module, a module with a large heat value is disposed at a position on the cooling plate closer toward the pipe than is a module with a small heat value.

3. The power conversion device of claim 2, wherein, among the plurality of inverter modules and the rectifier module, the module with the large heat value is disposed in a region on the cooling plate where the module with the large heat value overlaps the pipe in a plan view of the cooling mechanism.

4. The power conversion device of claim 2, wherein the plurality of inverter modules each include a plurality of switching element pairs each having two switching elements connected in series, the plurality of switching element pairs being connected in parallel.

5. The power conversion device of claim 2,
wherein, in each of the plurality of inverter modules, Si is used, and
wherein the plurality of inverter modules are disposed in a region on the cooling plate where the plurality of inverter modules overlap the pipe in a plan view of the cooling mechanism.

6. The power conversion device of claim 2,
wherein the plurality of inverter modules each have a wide-bandgap semiconductor, and
wherein the rectifier module is disposed in a region on the cooling plate where the rectifier module overlaps the pipe in a plan view of the cooling mechanism.

7. (canceled)

8. (canceled)

9. An air-conditioning apparatus, comprising:
the power conversion device of claim 1; a compressor configured to use the electric motor as a driving source; a heat-source-side heat exchanger; a load-side heat exchanger; a heat-source-side expansion valve; a load-side expansion valve; a controller; and a temperature sensor attached at least one module of the rectifier module and the plurality of inverter modules,
wherein a refrigerant circuit includes the compressor, the heat-source-side heat exchanger, the heat-source-side expansion valve, the load-side expansion valve, and the load-side heat exchanger that are sequentially connected by the pipe, and
wherein the controller is configured to control a flow rate of the refrigerant flowing through the pipe in such a manner that a temperature detected by the temperature sensor is higher than an outside air temperature and lower than a limit temperature of the at least one module to which the temperature sensor is attached.

10. The air-conditioning apparatus of claim 9, wherein the controller is configured to control opening and closing of at least one of the heat-source-side expansion valve and the load-side expansion valve to control the flow rate of the refrigerant flowing through the pipe.

11. (canceled)

12. (canceled)

13. (canceled)

14. (canceled)

15. The air-conditioning apparatus of claim 9, wherein the temperature sensor is a temperature detector attached to the rectifier module.

16. The air-conditioning apparatus of claim 9, wherein the temperature sensor is a temperature sensor contained in an inverter module, among the plurality of inverter modules, disposed at a position on the cooling plate closest to the rectifier module.
